(19) United States
(12) Patent Application Publication
(10) Pub. No.: US 2026/0060127 A1
(43) Pub. Date: Feb. 26, 2026

(54) Semiconductor Device and Method of Making a Chip-Scale Package

(71) Applicant: STATS ChipPAC Pte. Ltd., Singapore (SG)

(72) Inventors: Yi Jing Eric Chong, Singapore (SG); Abelardo Hadap Advincula, JR., Singapore (SG); Linda Pei Ee Chua, Singapore (SG)

(73) Assignee: STATS ChipPAC Pte. Ltd., Singapore (SG)

(21) Appl. No.: 18/814,152

(22) Filed: Aug. 23, 2024

(51) Int. Cl. H01L 21/56; H01L 21/02

(52) U.S. Cl. CPC H01L 21/563; H01L 21/02013

(57) ABSTRACT

A semiconductor device has a semiconductor wafer. A trench is formed through an active surface of the semiconductor wafer between a first semiconductor die and a second semiconductor die. An encapsulant is deposited in the trench. A back surface of the semiconductor wafer opposite the active surface is backgrinded using a rough grinder to expose the encapsulant. The back surface of the semiconductor wafer is backgrinded using a fine grinder. The fine grinder removes approximately 20 μm of thickness from the semiconductor wafer. Back-end manufacturing is performed on the wafer after depositing the encapsulant and before backgrinding using the rough grinder.

### FIELD OF THE INVENTION

The present invention relates in general to semiconductor devices and, more particularly, to semiconductor devices and methods of making a chip-scale package.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. Chip-scale packages have fairly minimal structural size so that the final package is hardly larger than the semiconductor die being packaged. However, as chips become thinner and smaller, chip-scale packaging methods and structures require technical advancement to keep up.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die 104 is formed on wafer 100 separated by a non-active, inter-die wafer area or saw street 106. Saw street 106 provides cutting areas to singulate semiconductor wafer 100 into individual bridge die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using a suitable metal deposition process. Conductive layer 112 operates as contact pads electrically connected to the circuits on active surface 110. In other embodiments, wafer 100 in FIGS. 1a-1c has been through front-end manufacturing but not back-end manufacturing. Therefore, the wafer will have been doped to form the different regions of transistors and other active components but may not have any conductive layers formed thereon when singulated in FIG. 1c.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

FIGS. 1d-1j illustrate a common method of chip-scale packaging for semiconductor die 104 in the prior art. FIG. 1d shows that, after singulation, the individual semiconductor die 104 are flipped and individually disposed onto a backgrinding tape or other carrier 120. Semiconductor die 104 are placed on carrier 120 with active surface 110 oriented toward the carrier. An encapsulant 130 is deposited over the semiconductor die in FIG. 1e. Encapsulant 130 is deposited completely over and covering back surfaces 108 of each semiconductor die 104. The combination of encapsulant 130 and semiconductor die 104 is referred to as a reconstituted wafer 132, because, in a sense, wafer 100 has been reconstituted as wafer 132 with encapsulant 130 connecting the semiconductor die instead of saw streets 106 of the original wafer material.

With encapsulant 130 deposited, carrier 120 is removed and back-end manufacturing occurs on reconstituted wafer 132. In FIG. 1f, back-end manufacturing has formed a build-up interconnect structure 140 over active surfaces 110 of semiconductor die 104. Interconnect structure 140 includes one or more insulating layers 142 interleaved with one or more conductive layers 144. Conductive layers 144 are formed and patterned to physically and electrically connect to contact pads 112, or to provide ohmic contact to doped semiconductor areas, and then fan-out electrical signals up to solder bumps 146. Solder bumps 146 are formed on contact pads or UBM of the top conductive layer 144.

After back-end manufacturing is complete, an important chip-scale packaging step is thinning down reconstituted wafer 132 for the final packages. FIG. 1g illustrates a grinder 150 used to remove a top portion of encapsulant 130 down to back surfaces 108 of semiconductor die 104, where line 152 is positioned. In some cases, as shown in FIG. 1h, grinding to line 152 is sufficient for the package being formed. In other cases, grinding continues to remove portions of both encapsulant 130 and semiconductor die 104 down to, e.g., line 156, as shown in FIG. 1i.

Reconstituted wafer 132 is singulated in FIG. 1j to separate each semiconductor die 104 into its own chip-scale package 160. Requirements these days are pushing packages to be thinner and thinner, so thinning the back surface of semiconductor die 104 more toward active surface 110 is required. However, backgrinding such thin die presents serious problems. A rough grinder 150 is typically used to quickly remove encapsulant 130. Unfortunately, a rough grinder 150 can form scratches and damage semiconductor die 104. Using a fine grinder 150 that would be less likely to scratch and damage semiconductor die 104 slows down manufacturing output to such an extent that the solution is untenable. Therefore, a need exists for improved chip-scale packaging methods and structures.

### BRIEF DESCRIPTION OF THE DRAWINGS

FIGS. 1a-1j illustrate forming a chip-scale package in the prior art;

FIGS. 2a-2l illustrate an improved method of forming a chip-scale package; and

FIGS. 3a and 3b illustrate an electronic device with the chip-scale package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

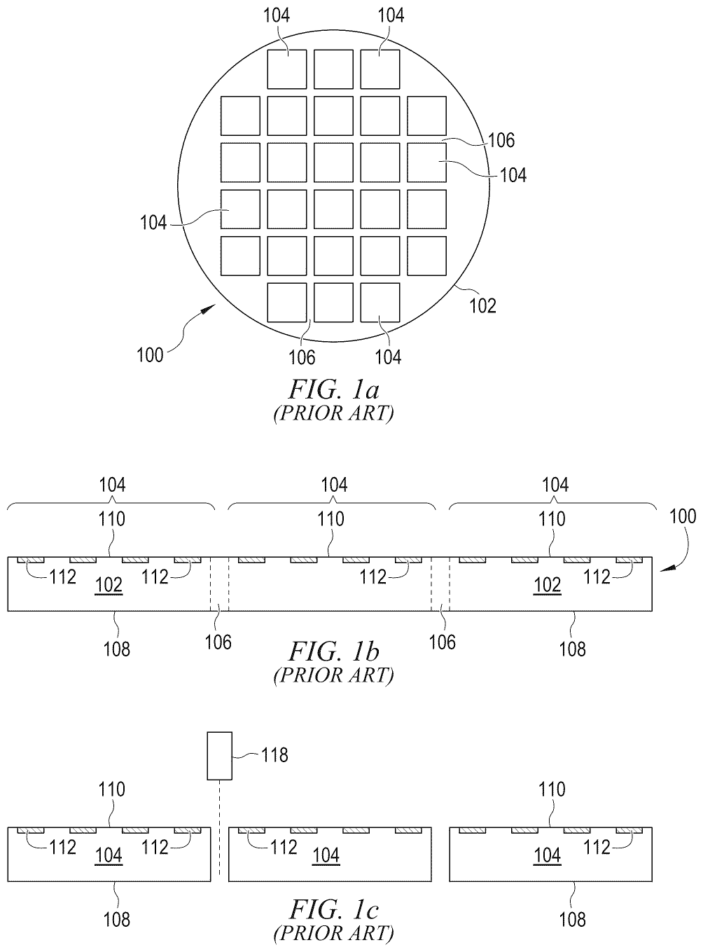

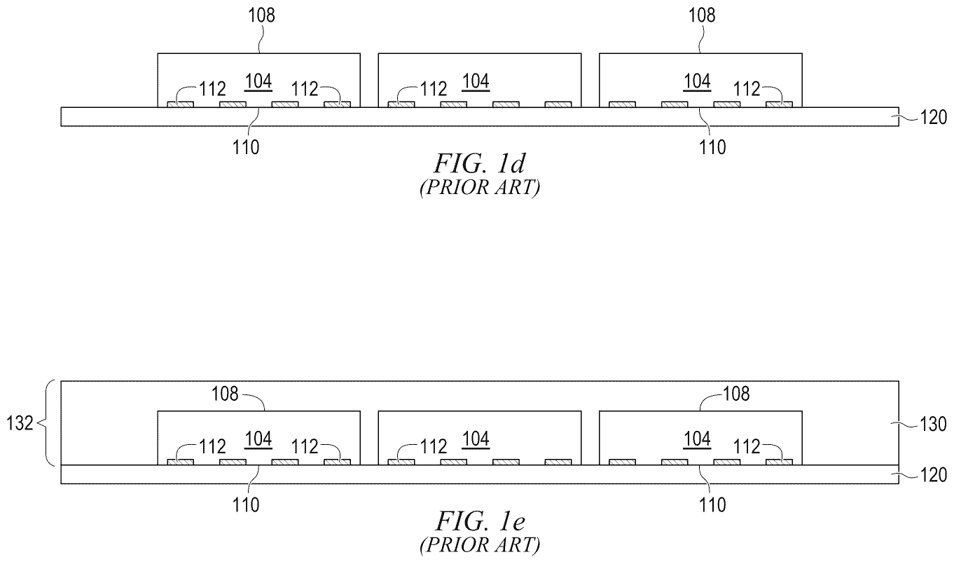

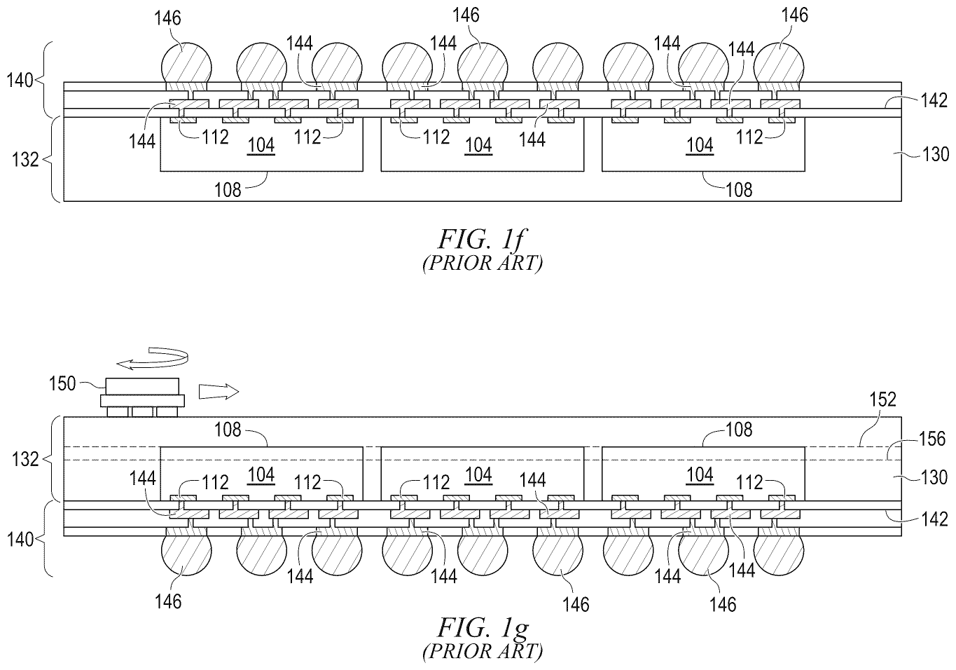

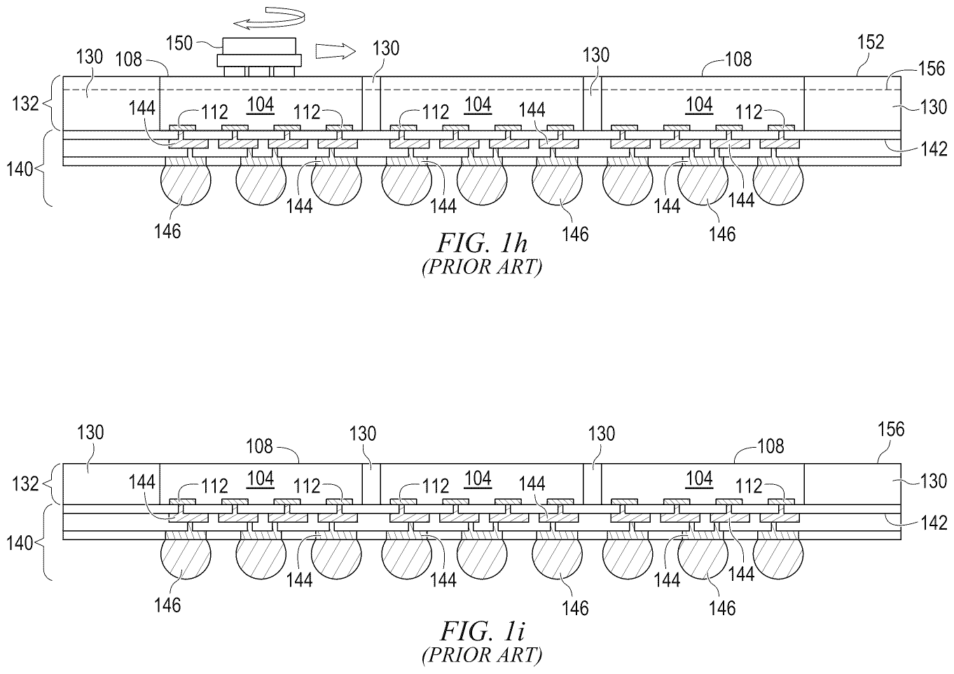

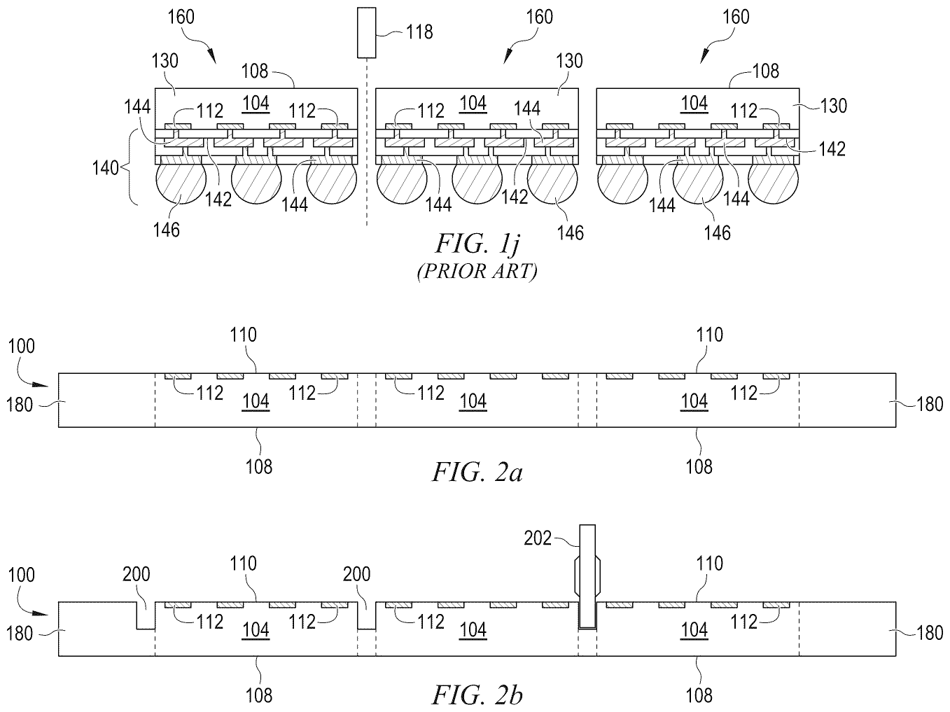

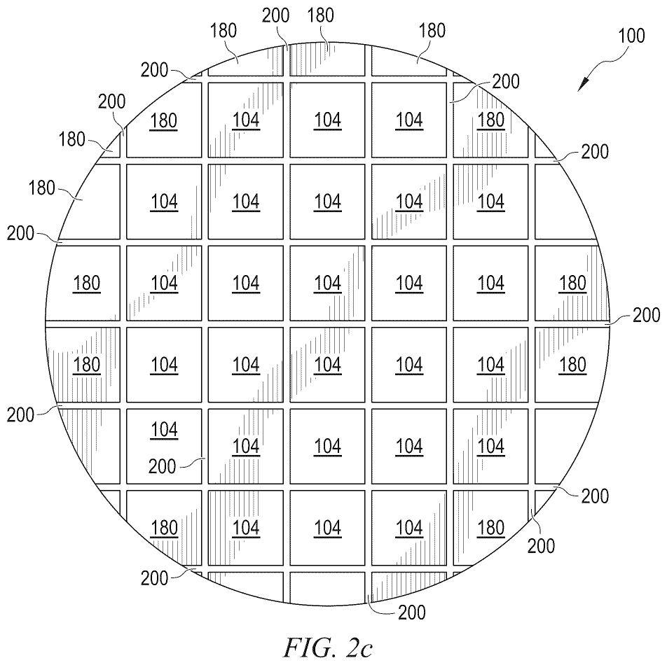

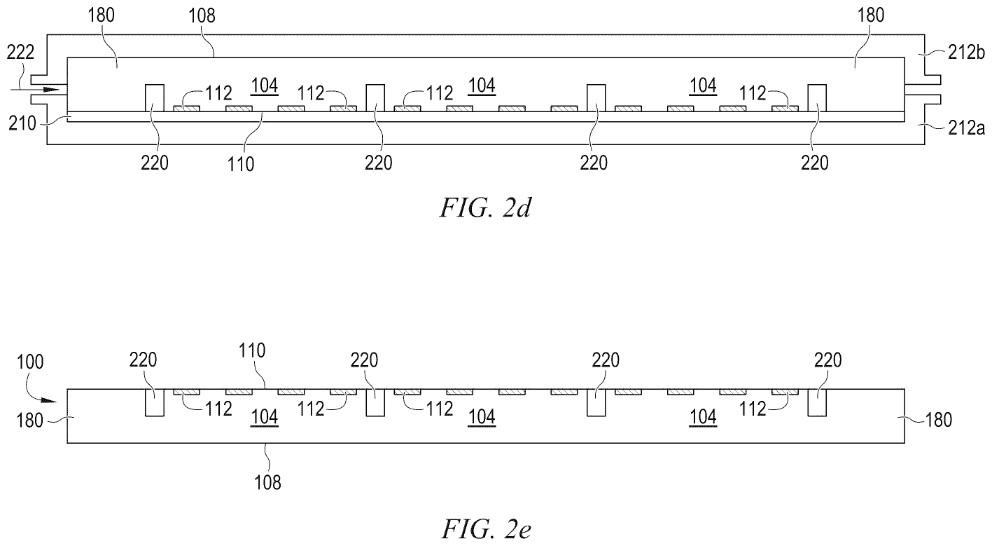

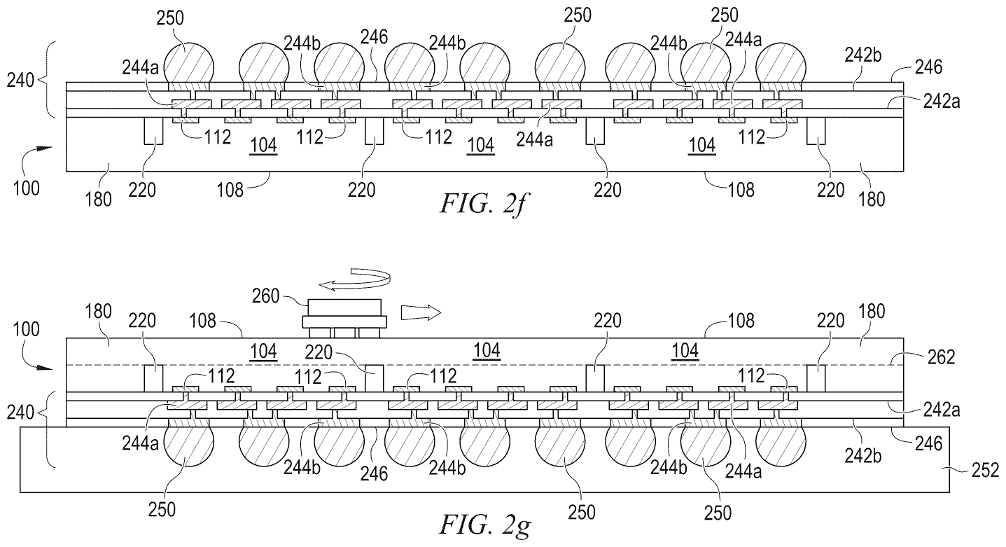

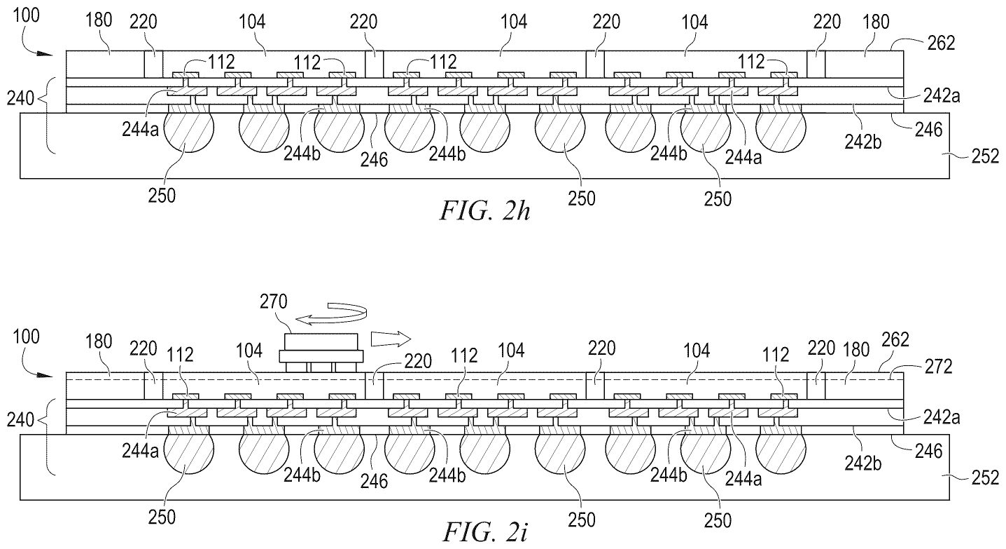

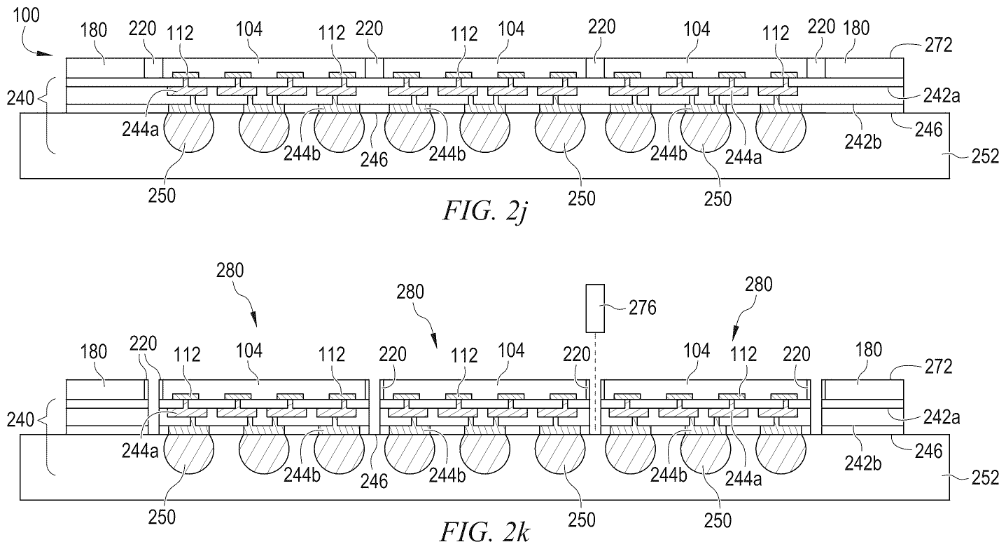

FIGS. 2a-2l show forming a chip-scale package using an improved process. FIG. 2a shows another cross-section of semiconductor wafer 100 with active surface 110 oriented up or otherwise available for processing. As described above, semiconductor wafer 100 may have undergone only front-end manufacturing, e.g., doping of the different active regions, without any conductive layers yet formed over active surface 110. In that case, contact pads 112 illustrated in FIG. 2a would actually be, or represent, regions of semiconductor material where ohmic contact will be made by a conductive layer during back-end manufacturing. In addition to having no conductive layers yet formed on active surface 110, wafer 100 in this state would usually have a only single passivation layer formed over the active surface for protection, e.g., by thermal oxidation, after front-end manufacturing is completed. In other embodiments, some conductive and insulating layers have been built up over semiconductor wafer 100 prior to the stage illustrated in FIG. 2a, and metal contact pads 112 are exposed at active surface 110. FIG. 2a shows some of the wasted space 180 around the outsides of wafer 100 that was not illustrated in FIG. 1b.

In FIG. 2b, trenches 200 are formed into active surface 110 of semiconductor wafer 100 in saw streets 106 using a saw blade 202 or other suitable tool. Trenches 200 are formed around every side of semiconductor die 104, including in space 180 around the outside of wafer 100. FIG. 2c shows a plan view with every semiconductor die 104 surrounded by trenches 200. In one embodiment, trenches 200 are formed to a depth from active surface 110 into wafer 100 that exceeds the desired final wafer thickness after backgrinding by 20 micrometers (μm), or approximately 20 μm. In one example, wafer 100 has a thickness, i.e., measured perpendicularly from back surface 108 to active surface 110, of 750 μm and the desired final thickness of semiconductor die 104 after backgrinding is 70 μm. In that example, trenches 200 are formed to a depth of 90 μm measured from active surface 110 perpendicularly to the bottom of the trenches. The +20 μm design rule can be applied to any desired final thickness and any starting wafer thickness.

In FIG. 2d, wafer 100 is laminated onto a thermal release tape 210 or other similar removable support structure and disposed into a mold 212. Mold 212 includes a bottom chase 212a and top chase 212b. An encapsulant 220 or other molding compound is inserted into an opening as indicated by arrow 222 to fill trenches 200. Release tape 210 is attached directly onto active surface 110 so that encapsulant 220 only fills trenches 200 without extending onto or over active surface 110.

In some embodiments, encapsulant 220 is deposited to fill trenches 200 using a paste printing, compressive molding, transfer molding, liquid encapsulant molding, vacuum lamination, spin coating, or another suitable applicator. Encapsulant 220 can be liquid or granular polymer composite material, such as epoxy resin, epoxy acrylate, or polymer, with or without an added filler. In another embodiment, encapsulant 220 is a laminated mold sheet or film with or without fillers. Encapsulant 220 is non-conductive, provides structural support, and environmentally protects semiconductor die 104 from external elements and contaminants. Encapsulant 220 can also be any of the materials and formed using any of the methods discussed below for insulating layers generally.

Wafer 100 is removed from mold 212 in FIG. 2e, and oriented with active surface 110 up or otherwise available for back-end processing. Thermal release layer 210 has been removed by an appropriate release mechanism.

In FIG. 2f, back-end processing is performed, creating a build-up interconnect structure 240. Interconnect structure 240 being called a build-up interconnect structure refers to the way that the interconnect structure is formed by successively building up insulating layers and conductive layers over semiconductor wafer 100 until the desired signal routing is achieved.

Forming interconnect structure 240 starts by forming an insulating layer 242a on wafer 100 and encapsulant 220. Insulating layer 242a contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 242a can be formed using physical vapor deposition (PVD), chemical vapor deposition (CVD), printing, lamination, spin coating, spray coating, sintering, or thermal oxidation.

Any insulating layer, passivation layer, dielectric layer, or encapsulant mentioned above or below can be formed using any of the materials or methods described for insulating layer 242a. Openings are formed through insulating layer 242a, and any passivation layer on active surface 110 from front-end manufacturing, to expose ohmic contacts or contact pads 112 of semiconductor die 104. The openings can be formed by chemical etching, photolithography, mechanical drilling, laser drilling, or any other suitable means. In some embodiments, a conductive layer is formed first on wafer 100, and then insulating layer 242a is formed. In cases where wafer 100 already has a passivation layer formed on active surface 110 for protection after front-end manufacturing, said passivation layer can be used as the first insulating layer of build-up interconnect structure 240.

A conductive layer 244a is formed on insulating layer 242a and through the openings in the insulating layer to physically and electrically couple to contact pads 112 or active surface 110. Conductive layer 244a includes conductive traces to fan-out or fan-in from semiconductor die 104, and optionally contact pads at both ends of the traces for connecting to the underlying contact and for subsequent formation of overlying conductive structures. Conductive layer 244a is formed using PVD, CVD, electrolytic plating, electroless plating, sputtering, or other suitable metal deposition process. Conductive layer 112 can be one or more layers of aluminum (Al), copper (Cu), tin (Sn), nickel (Ni), gold (Au), silver (Ag), or other suitable electrically conductive material. Any conductive layer described above or below can be formed using the same materials and methods described for conductive layer 244a.

Additional conductive layers 244 and insulating layers 242 are interleaved over wafer 100 as needed to implement the desired electrical signal routing. In the illustrated embodiments, two conductive layers 244a and 244b are formed for signal routing with two insulating layers 242a and 242b formed to support the conductive layers, respectively. Each successive conductive layer 244 is formed through openings of an underlying insulating layer 242 to electrically connect vertically through build-up interconnect structure 240. Any suitable number of insulating and conductive layers can be used to implement the desired signal routing.

After the desired number of conductive layers 244 and insulating layers 242 have been built up, contact pads or under-bump metallization (UBM) pads are optionally formed on the top conductive layer 244. UBM pads are optionally formed of multiple conductive layers including a wetting layer, barrier layer, and adhesion layer. A passivation or solder resist layer 246 is optionally formed over the top contact pad or UBM layer. Passivation layer 246 is formed of materials using methods as described above for insulating layers generally. Openings are formed in passivation layer 246 to expose contact pads or UBM pads for subsequent electrical interconnect. UBM pads can have a flat top surface as illustrated or be formed conformally in openings of passivation layer 246 or the top insulating layer 242.

In some embodiments, each insulating layer 242 and conductive layer 244 is etched to be completely removed over trenches 200, encapsulant 220, and saw streets 106 after being formed and before forming the next successive layer. Removing the layers between semiconductor die 104 as the layers are individually formed reduces manufacturing cost and complexity relative to singulating interconnect structure 240 with wafer 100 at a later step. Interconnect structure 240 would not be formed over the saw streets, so the ultimate singulation step would only have to cut through encapsulant 220.

An electrically conductive bump material is deposited over the top conductive layer 244 or overlying UBM using an evaporation, electrolytic plating, electroless plating, ball drop, or screen-printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 244b using a suitable attachment or bonding process. In one embodiment, the bump material is reflowed by heating the material above its melting point to form balls or bumps 250. Bump 250 can also be compression bonded or thermocompression bonded to conductive layer 244b. Bump 250 represents one type of interconnect structure that can be formed. The interconnect structure can also use bond wires, conductive paste, stud bump, micro bump, or other electrical interconnect. Any suitable combination of back-end processing steps can be performed in FIG. 2f.

After the desired back-end processing steps are completed, wafer 100 is flipped and mounted onto backgrinding tape 252 in FIG. 2g. Solder bumps 250 are oriented toward, and optionally embedded in, backgrinding tape 252. A rough or coarse grinder 260 is used on back surface 108 to reduce a thickness of wafer 100 by removing semiconductor material from the back surface. Rough grinder 260 is used to thin down wafer 100 to line 262, which is even with or coplanar to the bottom surfaces of trenches 200.

Rough grinder 260 thins down wafer 100 until encapsulant 220 is exposed as shown in FIG. 2h. Encapsulant 220 is used as an etch stop layer in some embodiments. Back surfaces of encapsulant 220 and semiconductor die 104 are now coplanar at line 262. In one embodiment, the remainder of wafer 100 within saw streets 106 is completely removed, which physically separates semiconductor die 104 from being connected by semiconductor material. Semiconductor die 104 remain connected by encapsulant 220, and interconnect structure 240 if the interconnect structure 240 was formed to extend across saw streets 106. In other embodiments, rough grinder 260 leaves a thin layer of semiconductor material over encapsulant 220, e.g., 5-10 μm of semiconductor wafer 100 remains over encapsulant 220 after rough grinder 260 is done.

Either way, rough grinder 260 does not thin wafer 100 all the way to the final thickness of die 104. Stopping rough grinder 260 short of the final thickness of semiconductor die 104 reduces the damage that the rough grinder causes to the die. Any deep scratches caused by rough grinder 260 will be subsequently removed.

FIG. 2i shows a fine grinder 270 being used to further thin wafer 100 down from line 262 to line 272. Line 272 represents the final desired thickness of semiconductor die 104. Fine grinder 270 is referred to as fine because it has a smaller grit size used to process the back surface of wafer 100 than rough grinder 260. In one embodiment, fine grinder 270 uses a fine mesh wheel and a gentler or lower grinding speed than rough grinder 260. A lower grinding speed refers to the rotational speed of fine grinder 270 being lower than the rotational speed of rough grinder 270 during grinding.

Fine grinder 270 is only used to reduce the thickness of wafer 100 by 20 μm, approximately 20 μm, or another relatively small thickness compared to the reduction in thickness done using rough grinder 260. In some embodiments, the thickness reduction by fine grinder 270 is considered relatively small when it is less than 5% of the thickness reduction by coarse grinder 260, or less than 50 μm. In the example above, where the beginning thickness of wafer 100 is 750 μm and the final desired thickness is 70 μm, coarse grinder 260 would reduce the wafer thickness by 660 μm. Fine grinder 270 reduces the wafer thickness by 20 μm, approximately 3% of the coarse grinder.

FIG. 2j shows wafer 100 thinned down to the final thickness of semiconductor die 104, e.g., 70 μm, with encapsulant 220 and die 104 having back surfaces coplanar at line 272. In FIG. 2k, wafer 100 is singulated using a saw blade or laser cutting tool 276 to separate semiconductor die 104 into individual chip-scale packages 280. A thin layer of encapsulant 220 is optionally left on the sides of semiconductor die 104. In other embodiments, encapsulant 220 is completely removed from the side surfaces of semiconductor die 104 and optionally some sacrificial area of semiconductor die 104 is removed as well. In some embodiments, an additional insulating backside protection layer is formed over the backs of semiconductor die 104 opposite interconnect structure 240, with or without completely removing encapsulant 220. The backside protection layer can be formed before singulation and using the methods and materials described above for insulating layers or encapsulants generally.

FIG. 2l shows a finished chip-scale package 280. Because fine grinder 270 was used to grind down semiconductor die 104 to its final thickness instead of rough grinder 260, semiconductor die 104 are less likely to be damaged and malfunction. Using rough grinder 260 for the bulk of the reduction saves time and money by using a faster and cheaper grinder. Using rough grinder 260 on only semiconductor wafer 100 and not additional encapsulant deposited between the semiconductor die reduces wear on the rough grinder and improves grinding speed. Finalizing the grinding with fine grinder 270 keeps rough grinder 260 from damaging the final die 104. Utilizing fine grinder 270 for only 20 μm of thickness reduction reduces wheel wear, thus reducing the manufacturing cost per wafer.

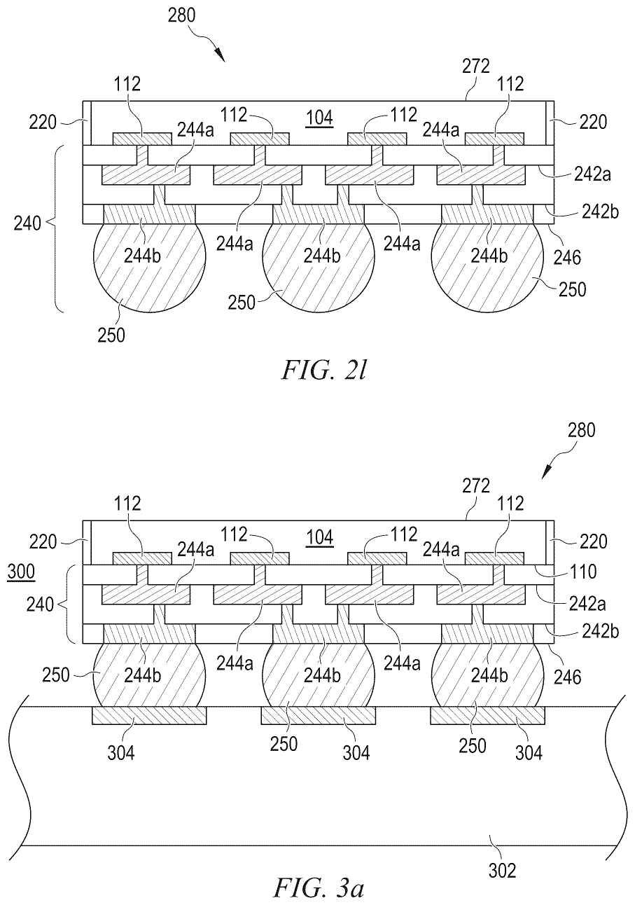

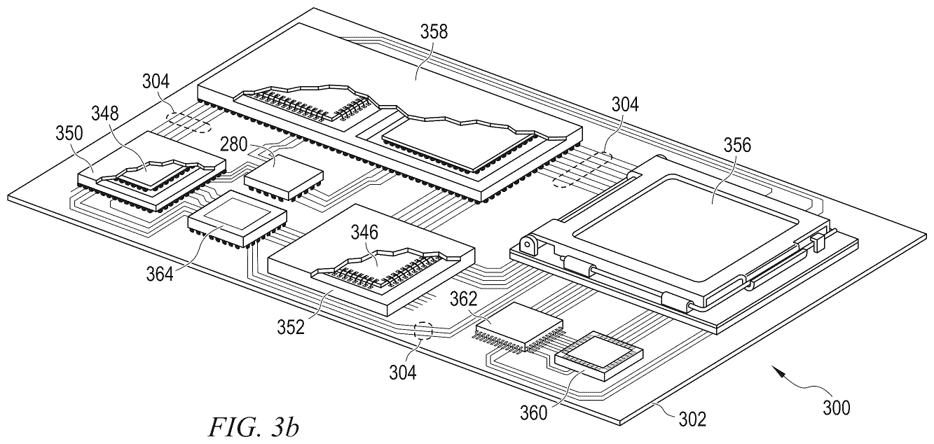

FIGS. 3a and 3b illustrate integrating the above-described semiconductor packages, e.g., chip-scale package 280, into a larger electronic device 300. FIG. 3a illustrates a partial cross-section of chip-scale package 280 mounted onto a printed circuit board (PCB) or other substrate 302 as part of electronic device 300. Solder bumps 250 are reflowed onto conductive layer 304 of PCB 302 to physically attach and electrically connect chip-scale package 280 to the PCB. In other embodiments, thermocompression or another suitable attachment and connection methods are used. In some embodiments, an adhesive or underfill layer is used between chip-scale package 280 and PCB 302. Semiconductor die 104 is electrically coupled to conductive layer 304 through interconnect structure 240.

FIG. 3b illustrates electronic device 300 having a chip carrier substrate or PCB 302 with a plurality of semiconductor packages disposed on a surface of PCB 302, including chip-scale package 280. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 3b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor wafer;
forming a trench through an active surface of the semiconductor wafer between a first semiconductor die and a second semiconductor die;
depositing an encapsulant in the trench;
backgrinding a back surface of the semiconductor wafer opposite the active surface using a rough grinder to expose the encapsulant; and
backgrinding the back surface of the semiconductor wafer using a fine grinder.

2. The method of claim 1, wherein the fine grinder removes approximately 20 μm of thickness from the semiconductor wafer.

3. The method of claim 1, further including performing back-end manufacturing on the wafer after depositing the encapsulant and before backgrinding using the rough grinder.

4. The method of claim 3, further including singulating the semiconductor wafer through the encapsulant after backgrinding using the fine grinder.

5. The method of claim 3, wherein performing back-end manufacturing includes forming a build-up interconnect structure over the active surface.

6. The method of claim 5, further including forming a solder bump over the build-up interconnect structure.

7. A method of making a semiconductor device, comprising:
providing a semiconductor wafer;
forming a trench through an active surface of the semiconductor wafer;
depositing an encapsulant in the trench;
backgrinding a back surface of the semiconductor wafer opposite the active surface using a rough grinder to expose the encapsulant; and
backgrinding the back surface of the semiconductor wafer using a fine grinder.

8. The method of claim 7, wherein the fine grinder removes approximately 20 μm of thickness from the semiconductor wafer.

9. The method of claim 8, wherein the rough grinder removes over 400 μm of thickness from the semiconductor wafer.

10. The method of claim 9, further including performing back-end manufacturing on the wafer after depositing the encapsulant and before backgrinding using the rough grinder.

11. The method of claim 10, further including singulating the semiconductor wafer through the encapsulant after backgrinding using the fine grinder.

12. The method of claim 10, wherein performing back-end manufacturing includes forming a build-up interconnect structure over the active surface.

13. The method of claim 12, further including forming a solder bump over the build-up interconnect structure.

14. A method of making a semiconductor device, comprising:
providing a semiconductor wafer;
forming a trench through an active surface of the semiconductor wafer;
depositing an encapsulant in the trench;
backgrinding a back surface of the semiconductor wafer opposite the active surface using a rough grinder; and
backgrinding the back surface of the semiconductor wafer using a fine grinder after using the rough grinder.

15. The method of claim 14, wherein the fine grinder removes approximately 20 μm of thickness from the semiconductor wafer.

16. The method of claim 15, wherein the rough grinder removes over 400 μm of thickness from the semiconductor wafer.

17. The method of claim 14, further including performing back-end manufacturing on the wafer after depositing the encapsulant and before backgrinding using the rough grinder.

18. The method of claim 17, further including singulating the semiconductor wafer through the encapsulant after backgrinding using the fine grinder.

19. The method of claim 17, wherein performing back-end manufacturing includes forming a build-up interconnect structure over the active surface.

20. The method of claim 19, further including forming a solder bump over the build-up interconnect structure.

21. A method of making a semiconductor device, comprising:
providing a semiconductor wafer;
backgrinding a surface of the semiconductor wafer using a rough grinder; and
backgrinding the surface of the semiconductor wafer using a fine grinder after using the rough grinder.

22. The method of claim 21, wherein the fine grinder removes approximately 20 μm of thickness from the semiconductor wafer.

23. The method of claim 22, wherein the rough grinder removes over 400 μm of thickness from the semiconductor wafer.

24. The method of claim 21, further including performing back-end manufacturing on the wafer before backgrinding using the rough grinder.

25. The method of claim 24, wherein performing back-end manufacturing includes forming a build-up interconnect structure over the surface.
